(19) United States
(12) Patent Application Publication
(10) Pub. No.: US 2025/0313010 A1
(43) Pub. Date: Oct. 9, 2025

(54) INKJET PRINTING APPARATUS AND INKJET PRINTING METHOD USING THE SAME

(71) Applicant: Samsung Display Co., LTD., Yongin-si (KR)

(72) Inventor: Jungwoong BYUN, Yongin-si (KR)

(21) Appl. No.: 18/991,630

(22) Filed: Dec. 22, 2024

(30) Foreign Application Priority Data
Apr. 9, 2024 (KR) 10-2024-0048015

(51) Int. Cl. B41J 2/165

(52) U.S. Cl. CPC B41J 2/16502; B41J 2/16523; B41J 2/16535; B41J 2/16579

(57) ABSTRACT

An inkjet printing apparatus includes: a base; a stage disposed on the base and capable of moving a substrate in a first direction; a first column part disposed on the base; a second column part disposed on the base and spaced apart from the first column part in the first direction; a head part configured to eject ink on the substrate at a fixed position and is disposed on the stage; and a head management part disposed between the first column part and the second column part and capable of moving in a second direction intersecting the first direction.

This application claims priority to Korean Patent Application No. 10-2024-0048015, filed on Apr. 9, 2024, and all the benefits accruing therefrom under 35 U.S.C. § 119, the content of which in its entirety is herein incorporated by reference.

### BACKGROUND

### 1. Field

The present disclosure relates generally to an inkjet printing apparatus. More particularly, the present disclosure relates to an inkjet printing apparatus and an inkjet printing method using the same.

### 2. Description of the Related Art

An inkjet printing apparatus including an inkjet head is used to form an orientation film or apply ultraviolet (“UV”) ink on a substrate in a process of manufacturing a liquid crystal display device. In addition, the inkjet printing apparatus is used to apply ink on a substrate in a process of manufacturing an organic light emitting display device.

After repeatedly ejecting the ink through the inkjet head, a process of cleaning and inspecting the inkjet head may be performed. To clean and inspect the inkjet head, the inkjet printing apparatus may further include a head management part. The head management part may be spaced apart from the inkjet head in a plan view during a process of ejecting the ink.

### SUMMARY

Embodiments provide an inkjet printing apparatus with improved precision.

Embodiments provide an inkjet printing method with improved precision.

An inkjet printing apparatus according to an embodiment of the present disclosure includes: a base; a stage disposed on the base and capable of moving a substrate in a first direction; a first column part disposed on the base; a second column part disposed on the base and spaced apart from the first column part in the first direction; a head part configured to eject ink on the substrate at a fixed position and is disposed on the stage; and a head management part disposed between the first column part and the second column part and capable of moving in a second direction intersecting the first direction.

In an embodiment, when the head management part is disposed between the first column part and the second column part, the head management part may be spaced apart from the head part in a plan view.

In an embodiment, the head part may define a workspace to which the ink is ejected. The workspace may overlap the head part in a plan view. After the head part ejects the ink on the substrate, the stage may move in the first direction so as to move away from the workspace.

In an embodiment, after the stage moves in the first direction away from the workspace, the head management part may move in the second direction toward the workspace.

In an embodiment, the head management part may include a head management apparatus configured to manage the head part and a head management frame on which the head management apparatus is loaded.

In an embodiment, the head management frame may be adjacent to each of the first column part and the second column part in the first direction and may have a U-shape in a side view.

In an embodiment, the head management apparatus may include a cleaning unit configured to clean the head part and an inspection unit configured to inspect the head part.

In an embodiment, the inkjet printing apparatus may further include a sub-head management part spaced apart from the stage in the first direction and capable of moving in the first direction.

In an embodiment, after the stage moves in the first direction away from the workspace, the sub-head management part may move in the first direction toward the workspace.

In an embodiment, the head management apparatus may include a cleaning unit configured to clean the head part, and the sub-head management part may include an inspection unit configured to inspect the head part.

In an embodiment, the head management apparatus may include an inspection unit configured to inspect the head part, and the sub-head management part may include a cleaning unit configured to clean the head part.

In an embodiment, the inkjet printing apparatus may further include an ink supply part configured to supply the ink to the head part and is disposed on the head part.

In an embodiment, the head part may be supported by a first structure, and the ink supply part may be supported by a second structure different from the first structure. The first structure and the second structure may be spaced apart from each other.

In an embodiment, each of the first column part and the second column part may be provided in plural. The plurality of first column parts may be spaced apart from each other in the second direction, and the plurality of second column parts may be spaced apart from each other in the second direction.

In an embodiment, the inkjet printing apparatus may further include a first bridge disposed on the plurality of first column parts, extending in the second direction, and connecting the plurality of first column parts; and a second bridge disposed on the plurality of second column parts, extending in the second direction, and connecting the plurality of second column parts.

In an embodiment, the head part may be fixed by the first bridge and the second bridge.

An inkjet printing method according to an embodiment of the present disclosure includes: providing a stage disposed on a base and on which a substrate is loaded, a first column part and a second column part spaced apart from each other in a first direction and disposed on the base, a head part disposed on the stage, and a head management part disposed between the first column part and the second column part; transporting the substrate in the first direction by the stage; ejecting ink on the substrate by the head part while a position of the head part is fixed; and transporting the head management part in a second direction intersecting the first direction to overlap the head part in a plan view.

In an embodiment, when the head management part is disposed between the first column part and the second column part, the head management part may be spaced apart from the head part in the plan view.

In an embodiment, the head part may define a workspace to which the ink is ejected. The workspace may overlap the head part in the plan view. After the ejecting of the ink on the substrate, the stage may move in the first direction so as to move away from the workspace.

In an embodiment, after the stage moves in the first direction away from the workspace, the head management part may move in the second direction toward the workspace.

In an embodiment, the inkjet printing method may further include cleaning the head part and inspecting the head part after the transporting of the head management part in the second direction.

In an embodiment, the inkjet printing method may further include providing a sub-head management part spaced apart from the stage in the first direction before the transporting of the substrate in the first direction.

In an embodiment, the inkjet printing method may further include transporting the sub-head management part in the first direction so as to overlap the head part in the plan view after the ejecting of the ink on the substrate.

In an embodiment, the inkjet printing method may further include cleaning the head part by the head management part after the transporting of the head management part in the second direction and inspecting the head part by the sub-head management part after the transporting of the sub-head management part in the first direction.

In an embodiment, the inkjet printing method may further include inspecting the head part by the head management part after the transporting of the head management part in the second direction and cleaning the head part by the sub-head management part after the transporting of the sub-head management part in the first direction.

An inkjet printing apparatus according to an embodiment of the present disclosure may include a stage disposed on a base and capable of moving a substrate in a first direction, a first column part disposed on the base, a second column part disposed on the base and spaced apart from the first column part in the first direction, a head part disposed on the stage and configured to eject ink on the substrate, and a head management part disposed between the first column part and the second column part and capable of moving in a second direction intersecting the first direction.

The head part may eject the ink on the substrate at a fixed position. As the position of the head part is fixed, the alignment accuracy between the head part and the substrate on which the ink is ejected may be effectively improved.

The head management part may be disposed between the first column part and the second column part during the process of ejecting the ink on the substrate. That is, the head management part may be spaced apart from the head part in a plan view during the process of ejecting the ink. Accordingly, the head management part may not interfere with movement of the stage. By forming the head management part in a form in which the head management part is accommodated between the first column part and the second column part, a size of the inkjet printing apparatus may be relatively effectively reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating an inkjet printing apparatus according to an embodiment of the present disclosure.

FIG. 2 is a front view illustrating the inkjet printing apparatus of FIG. 1.

FIGS. 3 and 4 are side views illustrating the inkjet printing apparatus of FIG. 1.

FIG. 5 is a perspective view illustrating a head part and a head management part included in the inkjet printing apparatus of FIG. 1.

FIGS. 6, 7, 8, 9, and 10 are views illustrating an inkjet printing method according to an embodiment of the present disclosure.

FIG. 11 is a plan view illustrating an inkjet printing apparatus according to another embodiment of the present disclosure.

FIG. 12 is a front view illustrating the inkjet printing apparatus of FIG. 11.

FIG. 13 is a side view illustrating the inkjet printing apparatus of FIG. 11.

FIG. 14 is a perspective view illustrating a head part, a head management part, and a sub-head management part included in the inkjet printing apparatus of FIG. 11.

### DETAILED DESCRIPTION

The terminology used herein is for the purpose of describing particular embodiments only and is not intended to be limiting. As used herein, “a”, “an,” “the,” and “at least one” do not denote a limitation of quantity and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element, it can be directly on the other element or intervening elements may be present therebetween. In contrast, when an element is referred to as being “directly on” another element, there are no intervening elements present. Hereinafter, embodiments of the present disclosure will be described in detail with reference to the accompanying drawings. The same reference numerals are used for the same components in the drawings, and redundant descriptions of the same components will be omitted.

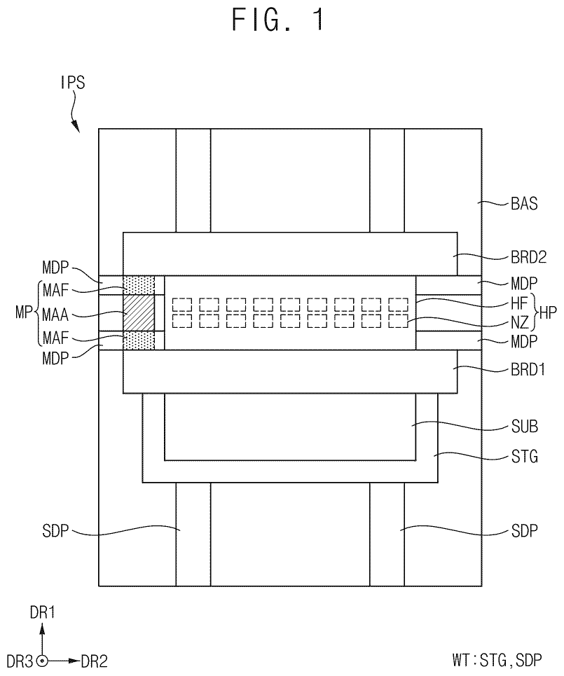

FIG. 1 is a plan view illustrating an inkjet printing apparatus according to an embodiment of the present disclosure.

In this specification, a “plane” may be defined by a first direction DR1 and a second direction DR2 intersecting the first direction DR1. For example, the first direction DR1 and the second direction DR2 may be perpendicular to each other. A direction normal to the plane, that is, a thickness direction of an inkjet printing apparatus IPS may be a third direction DR3. In other words, the third direction DR3 may be perpendicular to each of the first direction DR1 and the second direction DR2. As used herein, the “plan view” is a view in the thickness direction (i.e., DR3) of the inkjet printing apparatus IPS.

Referring to FIG. 1, the inkjet printing apparatus IPS according to an embodiment of the present disclosure may include a base BAS, a worktable WT, a first bridge BRD1, a second bridge BRD2, a head part HP, a head management part MP, and a head management driver MDP. The inkjet printing apparatus IPS may serve to form an orientation film or apply UV ink on a substrate in a process of manufacturing a liquid crystal display device, or to apply ink on a substrate in a process of manufacturing an organic light emitting display device.

The worktable WT may include a stage STG and a stage driver SDP. The head part HP may include a head frame HF and a plurality of nozzles NZ. The head management part MP may include a head management apparatus MAA and a head management frame MAF.

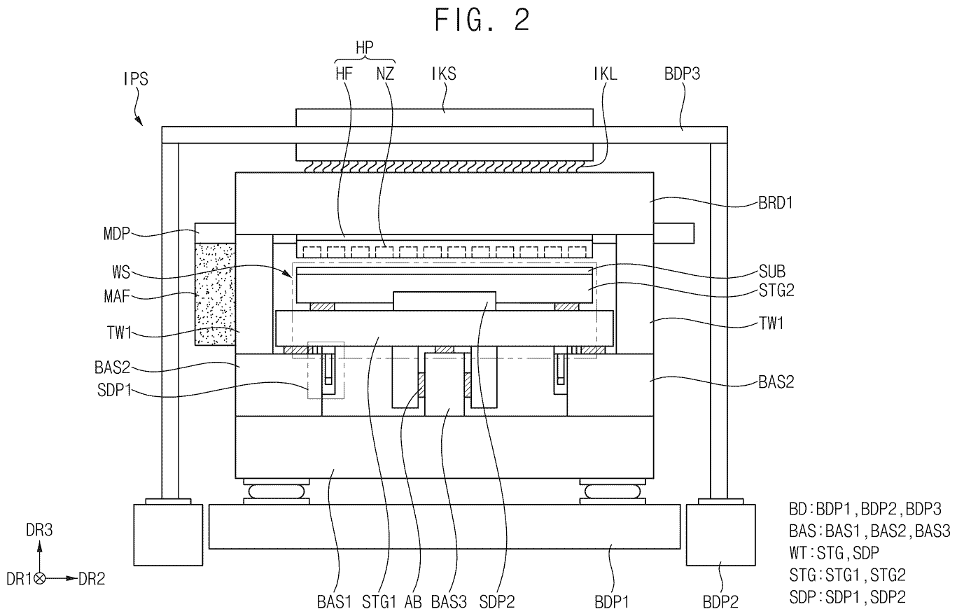

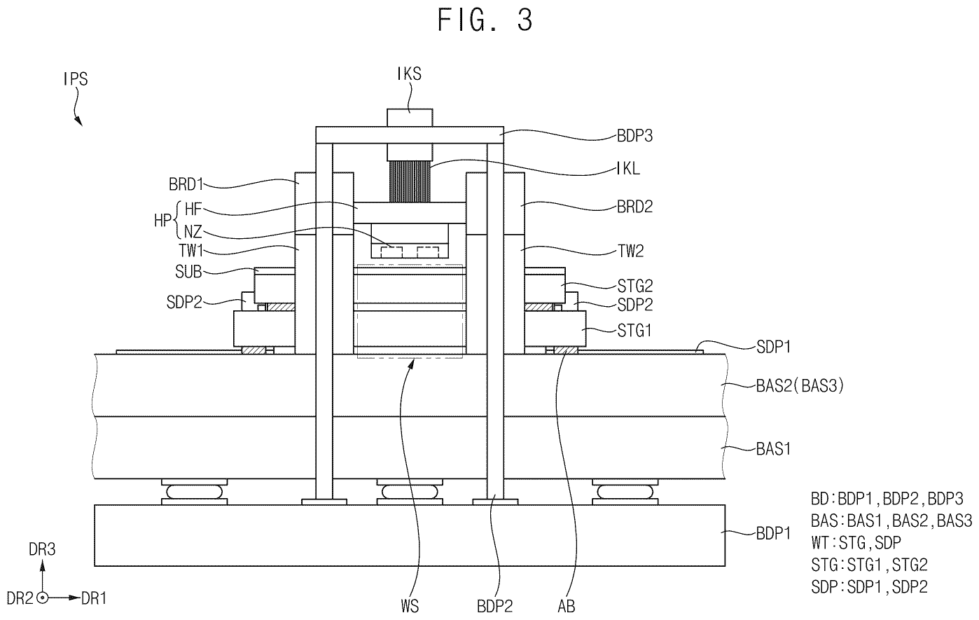

The base BAS may support structures disposed on an upper portion of the base BAS. For example, the base BAS may include granite, invar, polyetheretherketone (“PEEK”), or ceramic. In an embodiment, the base BAS may include granite. The base may limit a direction in which the worktable WT moves. A detailed description thereof will be described below with reference to FIGS. 2 and 3.

The stage STG may be disposed on the base BAS. A substrate SUB may be loaded on the stage STG. For example, the stage STG may include an electrostatic chuck that stationarily adsorbs the substrate SUB by electrostatic force. The stage STG may be moved in the first direction DR1 or in an opposite direction to the first direction DR1 by the stage driver SDP. To eject the ink on the substrate SUB, the stage STG may transport the substrate SUB in the first direction DR1 or in the opposite direction to the first direction DR1.

The substrate SUB may be disposed on the stage STG. Specifically, the substrate SUB may be disposed on an upper surface of the stage STG. The substrate SUB may be a target on which the ink is ejected. The substrate SUB may include a transparent material or an opaque material. For example, the substrate SUB may include glass or plastic.

The first bridge BRD1 and the second bridge BRD2 may be disposed on the stage STG. Although not illustrated in FIG. 1, the first bridge BRD1 may connect a plurality of first column parts (TW1, see FIG. 2), and the second bridge BRD2 may connect a plurality of second column parts (TW2, see FIG. 3). Each of the first bridge BRD1 and the second bridge BRD2 may extend in the second direction DR2.

The head part HP may be disposed on the stage STG. The head part HP may eject the ink on the substrate SUB. Specifically, the head part HP may include the head frame HF and the plurality of nozzles NZ positioned at a lower portion of the head frame HF. The plurality of nozzles NZ may eject the ink on the substrate SUB.

In exemplary embodiments, the head part HP may eject the ink on the substrate SUB at a fixed position. Specifically, the head frame HF may be disposed between the first bridge BRD1 and the second bridge BRD2. The head frame HF may directly contact each of the first bridge BRD1 and the second bridge BRD2. The head frame HF may be fixed by the first bridge BRD1 and the second bridge BRD2. As the head frame HF is fixed, the nozzles NZ may eject the ink on the substrate SUB at a fixed position.

The head management part MP may be disposed on the base BAS. The head management part MP may be disposed between the first bridge BRD1 and the second bridge BRD2. In addition, although not illustrated in FIG. 1, the head management part MP may be disposed between the first column part and the second column part. The head management part MP may be spaced apart from the head part HP in a plan view. The head management part MP may include the head management apparatus MAA and the head management frame MAF.

The head management apparatus MAA may be loaded on the head management frame MAF. The head management frame MAF may be moved in the second direction DR2 or in an opposite direction to the second direction DR2 by the head management driver MDP. To clean and inspect the head part HP, the head management frame MAF may transport the head management apparatus MAA in the second direction DR2 or in the opposite direction to the second direction DR2.

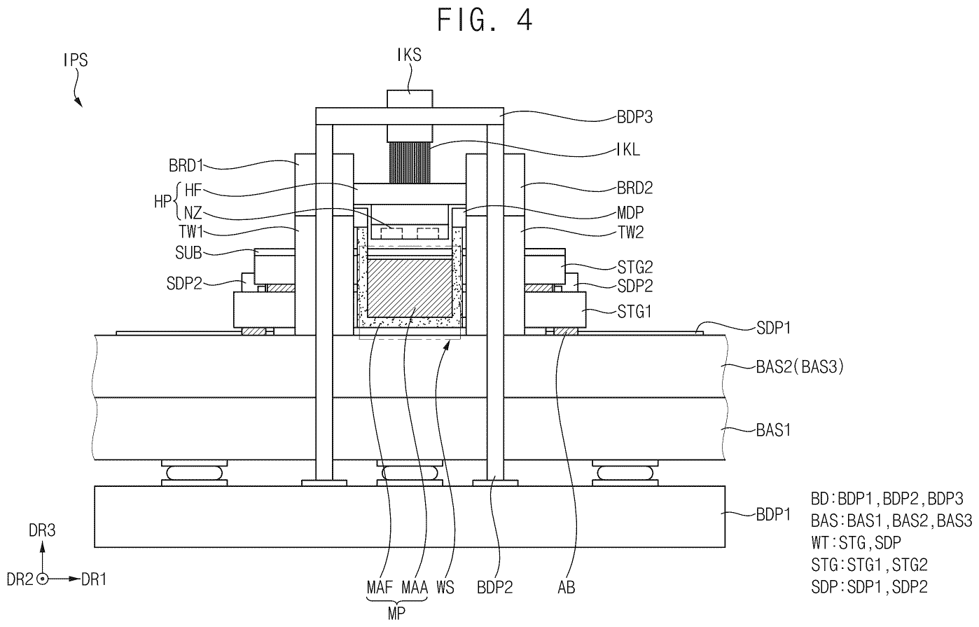

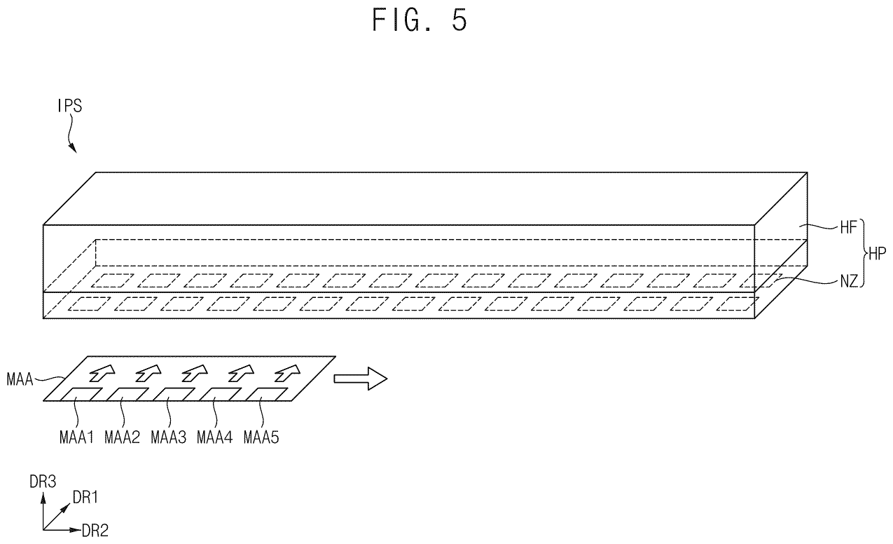

FIG. 2 is a front view illustrating the inkjet printing apparatus of FIG. 1. For example, FIG. 2 is a front view of the inkjet printing apparatus IPS as viewed from the first direction DR1. FIGS. 3 and 4 are side views illustrating the inkjet printing apparatus of FIG. 1. For example, FIGS. 3 and 4 are side views illustrating the inkjet printing apparatus IPS as viewed from the second direction DR2. In FIG. 3, the head management part MP included in the inkjet printing apparatus IPS is not illustrated. In FIG. 4, the head management part MP is illustrated. FIG. 5 is a perspective view illustrating a head unit and a head management part included in the inkjet printing apparatus of FIG. 1.

Referring to FIGS. 2, 3, 4, and 5, the inkjet printing apparatus IPS according to an embodiment of the present disclosure may include a body part BD, the base BAS, an air bearing AB, the worktable WT, a plurality of first column parts TW1, a plurality of second column parts TW2, the first bridge BRD1, the second bridge BRD2, the head part HP, an ink supply part IKS, an ink supply line IKL, the head management part MP, and the head management driver MDP.

The body part BD may include a first body part BDP1, a second body part BDP2, and a third body part BDP3. The base BAS may include a first base BAS1, a second base BAS2, and a third base BAS3.

The worktable WT may include the stage STG and the stage driver SDP. The stage STG may include a first stage STG1 and a second stage STG2. The stage driver SDP may include a first stage driver SDP1 and a second stage driver SDP2. The head part HP may include the head frame HF and the plurality of nozzles NZ. The head management part MP may include the head management apparatus MAA and the head management frame MAF.

The first body part BDP1 may support structures disposed on an upper portion of the first body part BDP1. The first body part BDP1 may contact a ground on which the inkjet printing apparatus IPS is disposed. For example, the first body part BDP1 may be referred to as an “isolation table”. In this case, the first body part BDP1 may reduce vibrations generated in the upper portion of the first body part BDP1.

The second body part BDP2 may be spaced apart from the first body part BDP1. The second body part BDP2 may contact the ground on which the inkjet printing apparatus IPS is disposed. The second body part BDP2 may be provided in a plurality. For example, the inkjet printing apparatus IPS may include four second body parts BDP2 spaced apart from each other. The second body parts BDP2 may be spaced apart from each other in the first direction DR1 and/or the second direction DR2. Each of the second body parts BDP2 may extend in the third direction DR3.

The third body part BDP3 may be spaced apart from the first body part BDP1 and may contact the second body parts BDP2. The third body part BDP3 may connect the second body parts BDP2 that are spaced apart from each other. The third body part BDP3 may extend in the second direction DR2. For example, the third body part BDP3 may have a rectangular planar shape. The third body part BDP3 may support the ink supply part IKS.

The first base BAS1 may be disposed on the first body part BDP1. The first base BAS1 may support structures disposed on an upper portion of the first base BAS1. The first base BAS1 may extend in the second direction DR2. For example, the first base BAS1 may have a rectangular planar shape.

The second base BAS2 may be disposed on the first base BAS1. Specifically, the second base BAS2 may be disposed on an upper surface of the first base BAS1. The second base BAS2 may be provided in a plurality. For example, the plurality of second bases BAS2 may be disposed at each of opposite sides of the first base BAS1. Each of the second bases BAS2 may extend in the first direction DR1. For example, each of the second bases BAS2 may have a rectangular planar shape. The second bases BAS2 may limit the direction in which the worktable WT moves together with the air bearing AB.

The third base BAS3 may be disposed on the first base BAS1. Specifically, the third base BAS3 may be disposed on the upper surface of the first base BAS1. The third base BAS3 may be spaced apart from the second bases BAS2 in the second direction DR2. The third base BAS3 may be disposed at a central portion of the first base BAS1. The third base BAS3 may extend in the first direction DR1. For example, the third base BAS3 may have a rectangular planar shape. The third base BAS3 may limit the direction in which the worktable WT moves together with the air bearing AB.

For example, each of the first base BAS1, the second base BAS2, and the third base BAS3 may include granite, invar, polyetheretherketone (PEEK), or ceramic. In an embodiment, each of the first base BAS1, the second base BAS2, and the third base BAS3 may include granite.

The air bearing AB may be disposed on the upper surface of each of the second bases BAS2, an upper surface of the third base BAS3, and opposite side surfaces of the third base BAS3. The air bearing AB may levitate the stage STG. The air bearing AB may reduce the generation of particles due to contact between structures when the stage STG moves.

The first stage STG1 may be disposed on the first base BAS1. The first stage STG1 may be levitated by the air bearing AB. Specifically, the first stage STG1 may include a first portion and a second portion connected to the first portion. The first portion of the first stage STG1 may be levitated by the air bearing AB disposed on the upper surface of each of the second bases BAS2 and the upper surface of the third base BAS3. The second portion of the first stage STG1 may be levitated by the air bearing AB disposed on opposite side surfaces of the third base BAS3.

The first stage STG1 may be limited in its movement direction by the second base BAS2, the third base BAS3, and the air bearing AB. For example, the first stage STG1 may not move in the second direction DR2 and the third direction DR3. The first stage STG1 may not rotate about a first rotation axis extending in the first direction DR1. The first stage STG1 may not rotate about a second rotation axis extending in the second direction DR2. The first stage STG1 may not rotate about a third rotation axis extending in the third direction DR3.

The first stage driver SDP1 may be provided in a plurality. For example, the plurality of first stage drivers SDP1 may be disposed on opposite sides of the first stage STG1, respectively. As illustrated in FIG. 2, the first stage drivers SDP1 may be spaced apart from each other in the second direction DR2. The first stage drivers SDP1 may move the first stage STG1. Specifically, the first stage drivers SDP1 may move the first stage STG1 in the first direction DR1 or in the opposite direction to the first direction DR1.

The air bearing AB may be further disposed on an upper surface of the first stage STG1. Specifically, the air bearing AB may be further disposed on opposite sides of the first stage STG1.

The second stage STG2 may be disposed on the first stage STG1. The second stage STG2 may be levitated by the air bearing AB disposed on the upper surface of the first stage STG1. The substrate SUB may be loaded on the second stage STG2. For example, the second stage STG2 may include an electrostatic chuck that stationarily adsorbs the substrate SUB by electrostatic force.

The second stage STG2 may be limited in its movement direction by the first stage STG1 and the air bearing AB. For example, the second stage STG2 may move in the first direction DR1 together with the first stage STG1. The second stage STG2 may not move in the third direction DR3. The second stage STG2 may not rotate about the first rotation axis extending in the first direction DR1. The second stage STG2 may not rotate about the second rotation axis extending in the second direction DR2.

The second stage driver SDP2 may be provided in a plurality. For example, the plurality of second stage drivers SDP2 may be disposed on opposite sides of the second stage STG2, respectively. As illustrated in FIG. 3, the second stage drivers SDP2 may be spaced apart from each other in the first direction DR1. Each of the second stage drivers SDP2 may move in the second direction DR2 or in the opposite direction to the second direction DR2.

The second stage drivers SDP2 may move the second stage STG2 in the second direction DR2 or in the opposite direction to the second direction DR2. Specifically, when the second stage drivers SDP2 move in the same direction, the second stage STG2 may move in the second direction DR2 or in the opposite direction to the second direction DR2. For example, when the second stage drivers SDP2 move in the second direction DR2, the second stage STG2 may move in the second direction DR2.

In addition, the second stage drivers SDP2 may rotate the second stage STG2 about the third rotation axis extending in the third direction DR3. Specifically, when the second stage drivers SDP2 move in different directions, the second stage STG2 may rotate about the third rotation axis extending in the third direction DR3. For example, in FIG. 3, when the second stage driver SDP2 adjacent to a left side of the second stage STG2 moves in the second direction DR2 and the second stage driver SDP2 adjacent to a right side of the second stage STG2 moves in the opposite direction to the second direction DR2, the second stage STG2 may rotate counterclockwise about the third rotation axis extending in the third direction DR3.

The first column parts TW1 may be disposed on the base BAS. Specifically, the first column parts TW1 may be disposed on upper surfaces of the second bases BAS2, respectively. The first column parts TW1 may be spaced apart from each other in the second direction DR2. Each of the first column parts TW1 may extend in the third direction DR3.

The second column parts TW2 may be disposed on the base BAS. Specifically, the second column parts TW2 may be disposed on the upper surfaces of the second bases BAS2, respectively. The second column parts TW2 may be spaced apart from the first column part TW1 in the first direction DR1. The second column parts TW2 may be spaced apart from each other in the second direction DR2. Each of the second column parts TW2 may extend in the third direction DR3.

For example, each of the first column parts TW1 and the second column parts TW2 may include granite, invar, polyetheretherketone (PEEK), or ceramic. In an embodiment, each of the first column parts TW1 and the second column parts TW2 may include granite.

The first bridge BRD1 may be disposed on the first column part TW1. The first bridge BRD1 may extend in the second direction DR2. The first bridge BRD1 may connect the first column parts TW1.

The second bridge BRD2 may be disposed on the second column part TW2. The second bridge BRD2 may be spaced apart from the first bridge BRD1 in the first direction DR1. The second bridge BRD2 may extend in the second direction DR2. The second bridge BRD2 may connect the second column parts TW2.

For example, each of the first bridge BRD1 and the second bridge BRD2 may include granite, invar, polyetheretherketone (PEEK), or ceramic. In an embodiment, each of the first bridge BRD1 and the second bridge BRD2 may include granite.

The head part HP may be disposed on the stage STG. The head part HP may include the head frame HF and the nozzles NZ positioned on the lower portion of the head frame HF. The head part HP may receive the ink from the ink supply part IKS through the ink supply line IKL.

The head part HP may define a workspace WS. The workspace WS may overlap the head part HP in a plan view. The workspace WS may be defined as a space in which the ink is ejected on the substrate SUB.

The head part HP may eject the ink on the substrate SUB at a fixed position. Specifically, the head frame HF may contact each of the first bridge BRD1 and the second bridge BRD2. The head frame HF may be fixed by the first bridge BRD1 and the second bridge BRD2. As the head part HP is fixed, the alignment accuracy between the head part HP and the substrate SUB on which the ink is ejected may be effectively improved.

The nozzles NZ may eject the ink on the substrate SUB. To eject the ink entirely on the substrate SUB with the head frame HF is fixed, a length in the second direction DR2 where the nozzles NZ are disposed may be greater than or equal to a length in the second direction DR2 of an area where the ink is ejected on the substrate SUB.

The ink supply part IKS may be disposed on the head part HP. The ink supply part IKS may include a reservoir in which the ink is stored and a pump that supplies the ink to the ink supply line IKL. The ink stored in the reservoir may be supplied to the head part HP through the ink supply line IKL. The ink supply part IKS may further include an ink supply driver. The ink supply driver part may include a driving circuit to generate a driving signal for the head part HP to eject the ink. Accordingly, the head part HP may eject the ink at a predetermined speed and a predetermined amount by the driving signal.

In an embodiment, the head part HP may be supported by a first structure, and the ink supply part IKS may be supported by a second structure different from the first structure, and the first structure and the second structure may be spaced apart from each other. For example, the head part HP may be supported by the first bridge BRD1 and the second bridge BRD2, and the ink supply part IKS may be supported by the third body part BDP3, and the first bridge BRD1 and the second bridge BRD2 may be spaced apart from the third body part BDP3. As the ink supply part IKS includes the pump for supplying the ink, the ink supply part IKS may generate continuous vibration. By supporting the head part HP and the ink supply part IKS on different structures, misalignment of the head part HP due to the vibration may be prevented. Accordingly, the precision of the head part HP may be effectively improved. However, the present disclosure is not limited thereto. In another embodiment, the head part HP and the ink supply part IKS may be supported by the same structure.

The head management part MP may be disposed on the base BAS. Specifically, as illustrated in FIG. 4, the head management part MP may be disposed between the first column part TW1 and the second column part TW2. The head management part MP may include the head management apparatus MAA and the head management frame MAF.

The head management apparatus MAA may be loaded on the head management frame MAF. In exemplary embodiments, as illustrated in FIG. 4, the head management frame MAF may have a U-shape. In other words, the head management frame MAF may include first portions adjacent to the first column part TW1 and the second column part TW2 in the first direction DR1, respectively, and a second portion connecting the first portions. Each of the first portions may extend in the third direction DR3, and the second portion may extend in the first direction DR1.

The head management driver MDP may move the head management frame MAF in the second direction DR2 or in the opposite direction to the second direction DR2. In an embodiment, the head management driver MDP may include a linear motion guide. However, the present disclosure is not limited thereto. In another embodiment, the head management driver MDP may include an air bearing.

The head management frame MAF may transport the head management apparatus MAA in the second direction DR2 or in the opposite direction to the second direction DR2. As illustrated in FIG. 5, since the head management apparatus MAA can move in the second direction DR2 or in the opposite direction to the second direction DR2, a length of the head management apparatus MAA in the second direction DR2 may be smaller than a length in the second direction DR2 in which the nozzles NZ are disposed. In addition, in order to correspond to all of the nozzles NZ, a length in the first direction DR1 of the head management apparatus MAA may be greater than or equal to a length in the first direction DR1 in which the nozzles NZ are disposed.

The head management apparatus MAA may include a plurality of head management units that manage the head part HP. The plurality of head management units may include a first head management unit MAA1, a second head management unit MAA2, a third head management unit MAA3, a fourth head management unit MAA4, and a fifth head management unit MAA5.

The first head management unit MAA1 may spray fluid toward the head part HP. In other words, the first head management unit MAA1 may spray fluid in the third direction DR3. In an embodiment, the first head management unit MAA1 may spray an inert gas. For example, the first head management unit MAA1 may be referred to as a “purge unit”.

The second head management unit MAA2 may suck fluid in the opposite direction to the third direction DR3. For example, the second head management unit MAA2 may be referred to as a “suction unit”.

The third head management unit MAA3 may remove a foreign substance adsorbed on the nozzles NZ. Specifically, the third head management unit MAA3 may remove the foreign substance by wiping the nozzles NZ. For example, the third head management unit MAA3 may be referred to as a “wiper unit”.

The first to third head management units MAA1, MAA2, MAA3 may clean the head part HP. Accordingly, the first to third head management units MAA1, MAA2, MAA3 may be referred to as “cleaning units”.

The fourth head management unit MAA4 may include a nozzle inspection optical system. The fourth head management unit MAA4 may inspect the condition of the nozzles NZ. Specifically, the fourth head management unit MAA4 may inspect positions of the nozzles NZ and whether the foreign substances are adsorbed on the nozzles NZ.

The fifth head management unit MAA5 may include an inspection film and an adhesion inspection optical system. The fifth head management unit MAA5 may inspect for an ejection defect of the nozzles NZ. Specifically, when the nozzles NZ eject ink on the inspection film, the adhesion inspection optical system may measure the ink present in the inspection film.

The fourth head management unit MAA4 and the fifth head management unit MAA5 may inspect the head part HP. Accordingly, the fourth head management unit MAA4 and the fifth head management unit MAA5 may be referred to as “inspection units”.

Each of the first to fifth head management units MAA1, MAA2, MAA3, MAA4, MAA5 may move in the first direction DR1. That is, in order to correspond to the nozzles NZ that are repeatedly arranged along the first direction DR1, each of the first to fifth head management units MAA1, MAA2, MAA3, MAA4, MAA5 may move in the first direction DR1 or in the opposite direction to the first direction DR1.

The head management part MP may be disposed between the first column part TW1 and the second column part TW2 during a process in which the head part HP ejects the ink on the substrate SUB. When the head management part MP is disposed between the first column part TW1 and the second column part TW2, the head management part MP may be spaced apart from the head part HP in a plan view. In other words, the head management part MP may be spaced apart from the workspace WS in a plan view. Accordingly, the head management part MP may not interfere with the movement of the first stage STG1 and the second stage STG2. By forming the head management part MP in a form in which the head management part MP is accommodated between the first column part TW1 and the second column part TW2, a size of the inkjet printing apparatus IPS may be relatively reduced. In other words, a length in the first direction DR1 of the inkjet printing apparatus IPS and/or a length in the second direction DR2 of the inkjet printing apparatus IPS may be relatively reduced.

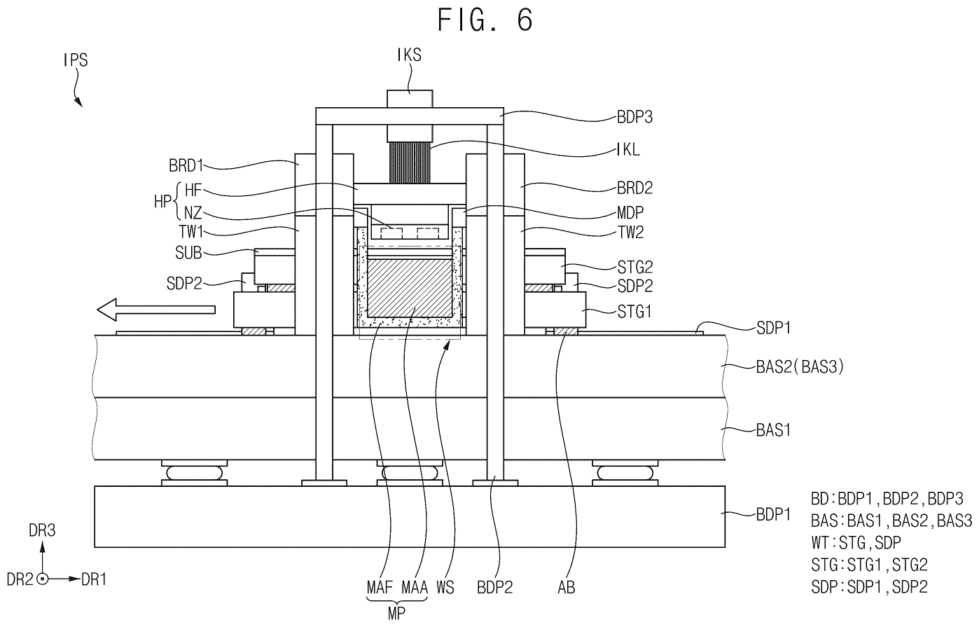

In the process of managing the head part HP after the process of ejecting the ink on the substrate SUB, the head management part MP may move in the second direction DR2 toward the workspace WS. A detailed description thereof will be described below with reference to FIGS. 6 to 10.

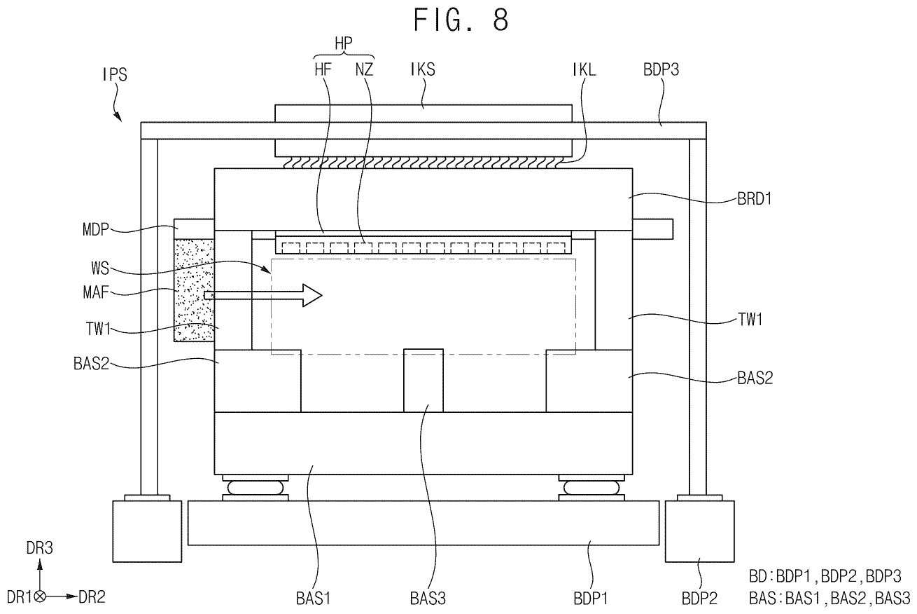

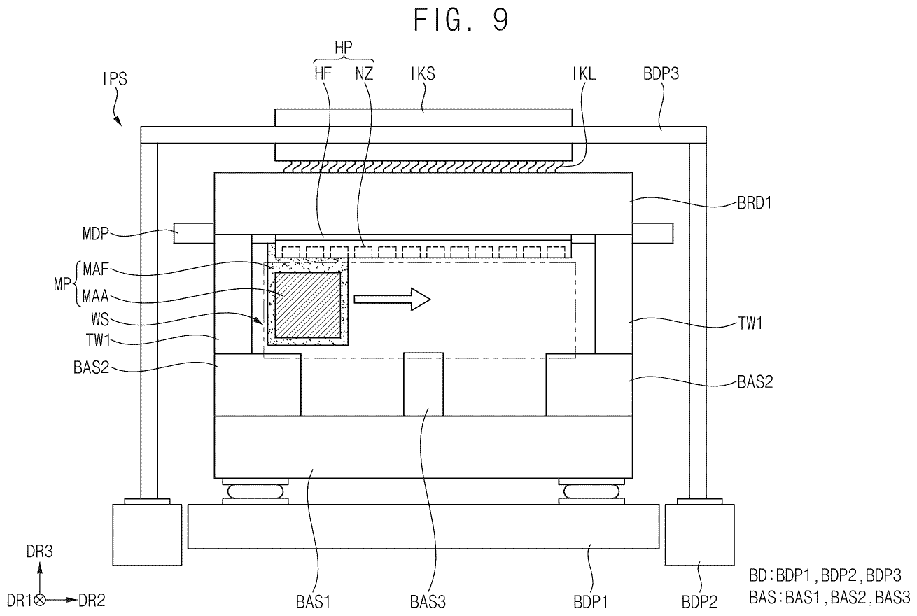

FIGS. 6, 7, 8, 9, and 10 are views illustrating an inkjet printing method according to an embodiment of the present disclosure. For example, an inkjet printing method described below with reference to FIGS. 6 to 10 may be performed using the inkjet printing apparatus IPS described above with reference to FIGS. 1 to 5. Hereinafter, redundant descriptions of the inkjet printing apparatus IPS described above with reference to FIGS. 1 to 5 may be omitted or may be summarized. In FIGS. 8 and 9, the worktable WT including the first stage STG1, the first stage driver SDP1, the second stage STG2, and the second stage driver SDP2 is not illustrated.

Referring to FIG. 6, the first stage STG1 may transport the substrate SUB in the first direction DR1 or in the opposite direction to the first direction DR1. The second stage STG2 may be levitated by the air bearing AB disposed on the upper surface of the first stage STG1, so that when the first stage STG1 moves, the second stage STG2 and the substrate SUB loaded on the second stage STG2 may move together with the first stage STG1.

The first stage STG1 may be moved in the opposite direction to the first direction DR1 by the first stage driver SDP1. Accordingly, the substrate SUB may be transported in the opposite direction to the first direction DR1 toward the head part HP. The substrate SUB may move to a lower portion of the head part HP, and ink may be ejected on the substrate SUB by the nozzles NZ. At this time, the position of the head part HP may be fixed.

After the first stage STG1 moves in the opposite direction to the first direction DR1, the second stage STG2 may be moved in the second direction DR2 or in the opposite direction to the second direction DR2 by the second stage driver SDP2. In addition, the second stage STG2 may be rotated about the third rotation axis extending in the third direction DR3 by the second stage driver SDP2. That is, after printing the ink once on the substrate SUB, in order to obtain a nozzle mixing effect, the second stage STG2 may move slightly in the second direction DR2 or in the opposite direction to the second direction DR2, and the second stage STG2 may be rotated about the third rotation axis.

After the second stage STG2 moves, the first stage STG1 may be moved in the first direction DR1 by the first stage driver SDP1. Accordingly, the substrate SUB may be transported in the first direction DR1 toward the head part HP. The substrate SUB may move again to the lower portion of the head part HP, and the ink may be ejected on the substrate SUB by the nozzles NZ. Accordingly, the ink may be printed twice on the substrate SUB. By repeating the process as described above, the process of ejecting the ink on the substrate SUB may be performed. At this time, the head management part MP may be disposed between the first column part TW1 and the second column part TW2. In other words, the head management part MP may be spaced apart from the workspace WS in a plan view. Accordingly, the head management part MP may not interfere with the movement of the first stage STG1 and the second stage STG2.

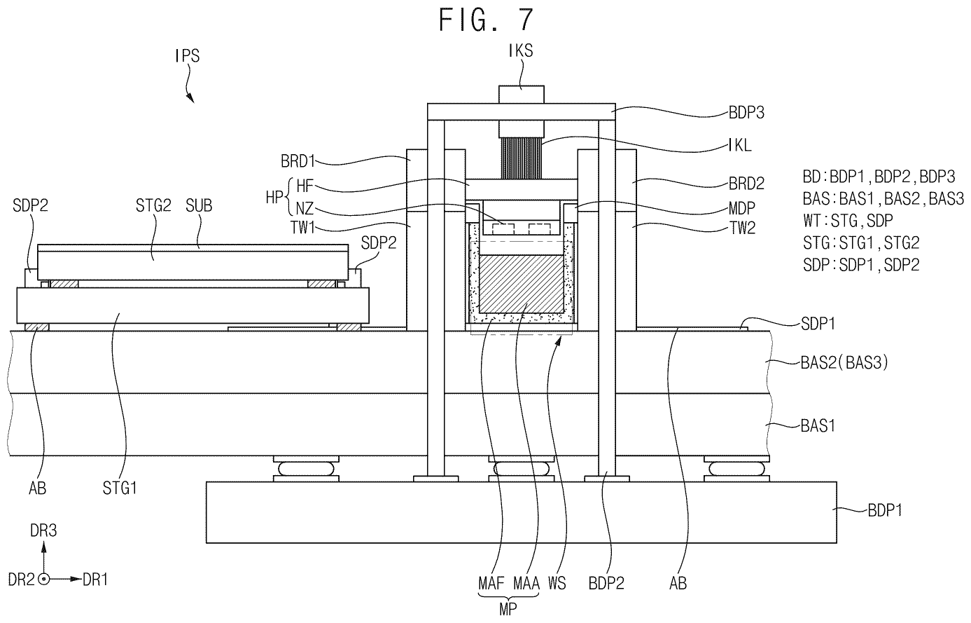

Referring to FIG. 7, after the process of ejecting the ink on the substrate SUB, the first stage STG1 and the second stage STG2 may move in the first direction DR1 or in the opposite direction to the first direction DR1. Specifically, the first stage STG1 and the second stage STG2 may move in the first direction DR1 or in the opposite direction to the first direction DR1 so as to move away from the workspace WS. In this case, the first stage STG1 and the second stage STG2 may be spaced apart from the head part HP in a plan view.

Referring to FIGS. 8 and 9, in the process of managing the head part HP after the process of ejecting the ink on the substrate SUB, the head management part MP may be moved in the second direction DR2 by the head management driver MDP so as to overlap the head part HP in a plan view. In other words, the head management part MP may move in the second direction DR2 toward the workspace WS. At this time, the first stage STG1 and the second stage STG2 may be spaced apart from the head part HP and the workspace WS in a plan view. Accordingly, the first stage STG1 and the second stage STG2 may not interfere with the movement of the head management part MP.

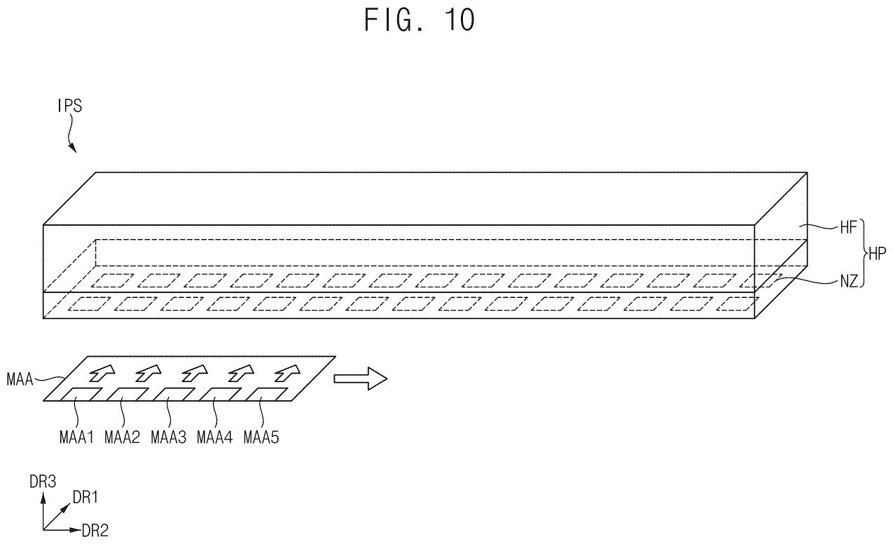

Referring to FIG. 10, the head management apparatus MAA included in the head management part MP may manage the head part HP. Specifically, the head management apparatus MAA may clean the head part HP and inspect the head part HP.

To correspond to the nozzles NZ repeatedly arranged along the second direction DR2, the head management apparatus MAA may move in the second direction DR2 or in the opposite direction to the second direction DR2. The head management apparatus MAA may include the first to fifth head management units MAA1, MAA2, MAA3, MAA4, MAA5.

The first to third head management units MAA1, MAA2, MAA3 may clean the head part HP. The fourth and fifth head management units MAA4, MAA5 may inspect the head part HP. To correspond to the nozzles NZ repeatedly arranged along the first direction DR1, each of the first to fifth head management units MAA1, MAA2, MAA3, MAA4, MAA5 may move in the first direction DR1 or in the opposite direction to the first direction DR1.

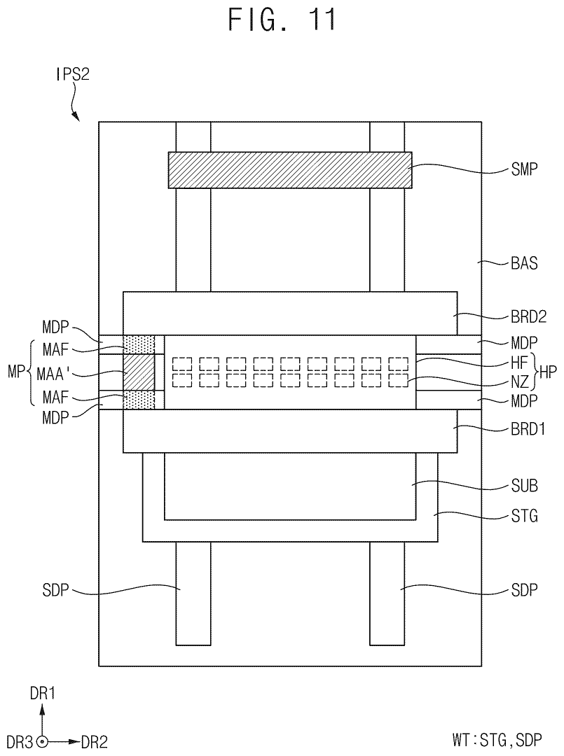

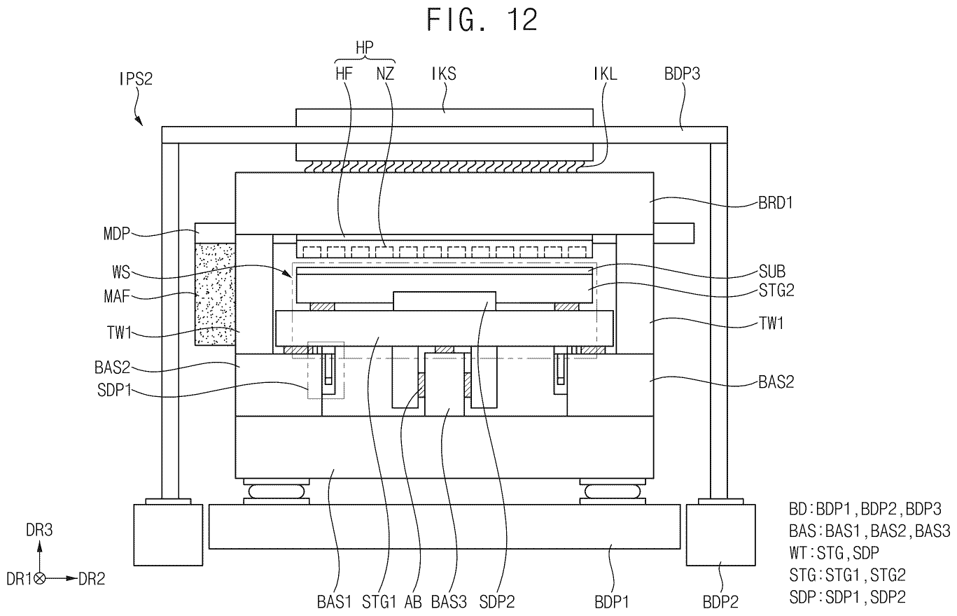

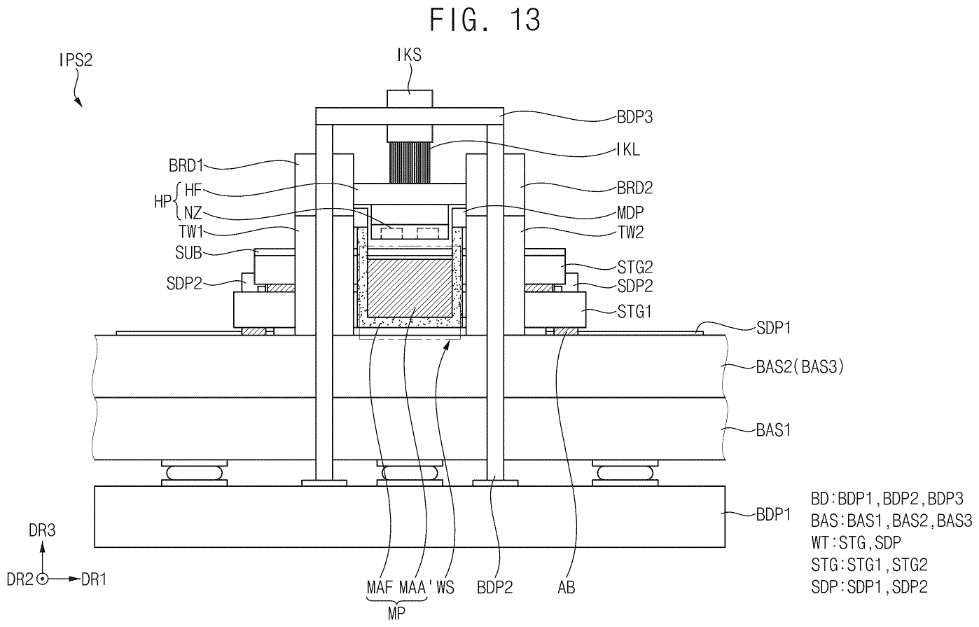

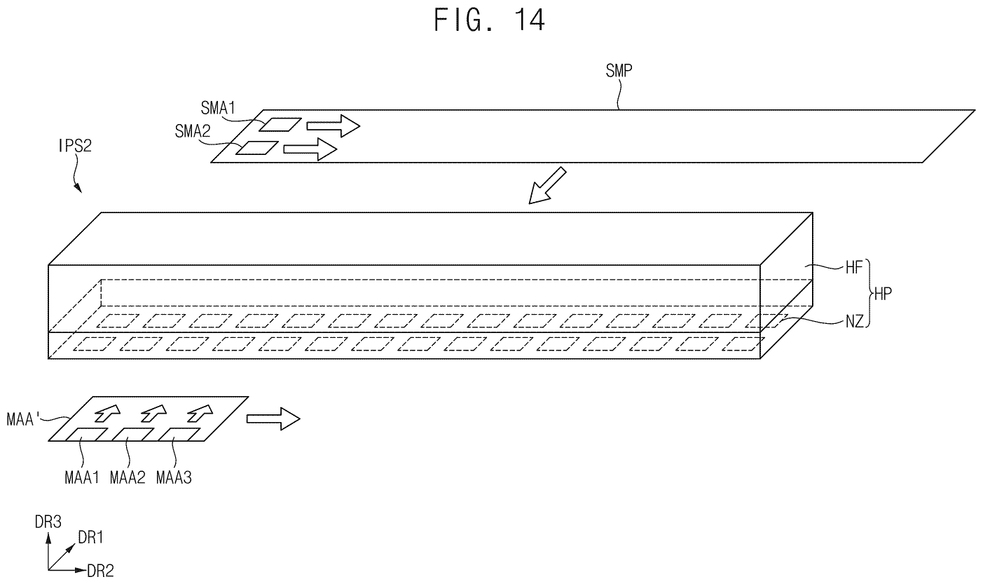

FIG. 11 is a plan view illustrating an inkjet printing apparatus according to another embodiment of the present disclosure. FIG. 12 is a front view illustrating the inkjet printing apparatus of FIG. 11. For example, FIG. 12 is a front view illustrating the inkjet printing apparatus IPS2 viewed from the first direction DR1. FIG. 13 is a side view illustrating the inkjet printing apparatus of FIG. 11. For example, FIG. 13 is a side view illustrating the inkjet printing apparatus IPS2 viewed from the second direction DR2. FIG. 14 is a perspective view illustrating a head part, a head management part, and a sub-head management part included in the inkjet printing apparatus of FIG. 11.

Referring to FIGS. 11, 12, 13, and 14, an inkjet printing apparatus IPS2 according to another embodiment of the present disclosure may include the body part BD, the base BAS, the air bearing AB, the worktable WT, the plurality of first column parts TW1, the plurality of second column parts TW2, the first bridge BRD1, the second bridge BRD2, the head part HP, the ink supply part IKS, the ink supply line IKL, a head management part MP, a head management driver MDP, and a sub-head management part SMP.

The worktable WT may include the stage STG and the stage driver SDP. The stage STG may include the first stage STG1 and the second stage STG2. The stage driver SDP may include the first stage driver SDP1 and the second stage driver SDP2.

The inkjet printing apparatus IPS2 may be substantially the same as the inkjet printing apparatus IPS described above with reference to FIGS. 1 to 5, except that the inkjet printing apparatus IPS2 further includes the sub-head management part SMP spaced apart from the stage STG in the first direction DR1. Hereinafter, redundant descriptions of the inkjet printing apparatus IPS described above with reference to FIGS. 1 to 5 may be omitted or may be summarized.

The head part HP may eject ink on the substrate SUB at a fixed position. As the position of the head part HP is fixed, the alignment accuracy between the head part HP and the substrate SUB on which the ink is ejected may be effectively improved.

The head part HP may define the workspace WS. The workspace WS may overlap the head part HP in a plan view. The workspace WS may be defined as a space in which the ink is ejected on the substrate SUB.

The head management part MP may be disposed between the first column part TW1 and the second column part TW2. The head management part MP may include a head management apparatus MAA′ and the head management frame MAF.

The head management apparatus MAA′ may be loaded on the head management frame MAF. In exemplary embodiments, as illustrated in FIG. 13, the head management frame MAF may have a U-shape. The head management driver MDP may move the head management frame MAF in the second direction DR2 or in the opposite direction to the second direction DR2.

As illustrated in FIG. 11, the sub-head management part SMP may be disposed on the base BAS. The sub-head management part SMP may be spaced apart from the stage STG in the first direction DR1. The sub-head management part SMP may be moved in the first direction DR1 or in the opposite direction to the first direction DR1 by a sub-head management driver.

As illustrated in FIG. 14, the sub-head management part SMP may move in the first direction DR1 or in the opposite direction to the first direction DR1, so that a length in the first direction DR1 of the sub-head management part SMP may be smaller than a length in the first direction DR1 in which the nozzles NZ are disposed. In addition, in order to correspond to all of the nozzles NZ, a length in the second direction DR2 of the sub-head management part SMP may be greater than or equal to a length in the second direction DR2 in which the nozzles NZ are disposed.

The head management apparatus MAA′ may include a plurality of head management units that manage the head part HP. The plurality of head management units may include the first head management unit MAA1, the second head management unit MAA2, and the third head management unit MAA3.

The first head management unit MAA1 may spray fluid toward the head part HP (e.g., in the third direction DR3). The second head management unit MAA2 may suck fluid in the opposite direction of the third direction DR3. The third head management unit MAA3 may remove a foreign substance adsorbed on the nozzles NZ. The first to third head management units MAA1, MAA2, MAA3 may clean the head part HP. Accordingly, the first to third head management units MAA1, MAA2, MAA3 may be referred to as “cleaning units”.

The sub-head management part SMP may include a plurality of sub-head management units that manage the head part HP. The plurality of sub-head management units may include a first sub-head management unit SMA1 and a second sub-head management unit SMA2.

The first sub-head management unit SMA1 may include a nozzle inspection optical system. The first sub-head management unit SMA1 may inspect positions of the nozzles NZ and whether the foreign substances are adsorbed on the nozzles NZ. The second sub-head management unit SMA2 may include an inspection film and an adhesion inspection optical system. The second sub-head management unit SMA2 may inspect the ejection defects of the nozzles NZ. The first sub-head management unit SMA1 and the second sub-head management unit SMA2 may inspect the head part HP. Accordingly, the first sub-head management unit SMA1 and the second sub-head management unit SMA2 may be referred to as “inspection units”.

In an embodiment, the cleaning unit and the inspection unit may be included in different management parts. For example, the cleaning unit may be included in the head management part MP, and the inspection unit may be included in the sub-head management part SMP. Accordingly, in the process of cleaning the head part HP with the cleaning unit, the inspection unit may be prevented from being contaminated.

In an embodiment, the head management part MP may include the cleaning unit and the sub-head management part SMP may include the inspection unit. That is, the inspection unit requiring relatively higher precision than the cleaning unit may be included in the sub-head management part SMP. The cleaning unit requiring relatively lower precision than the inspection unit may be included in the head management part MP. However, the present disclosure is not limited thereto.

In an embodiment, the head management part MP may include the inspection unit and the sub-head management part SMP may include the cleaning unit. That is, the inspection unit requiring relatively higher precision than the cleaning unit may be included in the head management part MP. In this case, the head management driver MDP that drives the head management part MP may include an air bearing. When the head management driver MDP includes the air bearing, the head management part MP may move more precisely compared to when the head management driver MDP includes only a linear motion guide. The cleaning unit requiring relatively lower precision than the inspection unit may be included in the sub-head management part SMP.

Hereinafter, an inkjet printing method using the inkjet printing apparatus IPS2 described above with reference to FIGS. 11 to 14 will be described below. Redundant descriptions of the inkjet printing method described above with reference to FIGS. 6 to 10 may be omitted or may be summarized.

After the process of ejecting the ink on the substrate SUB, the first stage STG1 and the second stage STG2 may move in the first direction DR1 or in the opposite direction to the first direction DR1. In other words, the first stage STG1 and the second stage STG2 may move in the first direction DR1 or in the opposite direction to the first direction DR1 so as to move away from the workspace WS. In this case, the first stage STG1 and the second stage STG2 may be spaced apart from the head part HP in a plan view.

In the process of managing the head part HP after the process of ejecting the ink on the substrate SUB, the head management part MP may move in the second direction DR2 so as to overlap the head part HP in a plan view. In other words, the head management part MP may move in the second direction DR2 toward the workspace WS.

In addition, in the process of managing the head part HP, the sub-head management part SMP may move in the opposite direction to the first direction DR1 so as to overlap the head part HP in a plan view. In other words, the sub-head management part SMP may move in the opposite direction to the first direction DR1 toward the workspace WS.

For example, moving the head management part MP in the second direction DR2 may be performed before moving the sub-head management part SMP in the opposite direction to the first direction DR1. However, the present disclosure is not limited thereto. For another example, the moving the head management part MP in the second direction DR2 may be performed after the moving of the sub-head management part SMP in the opposite direction to the first direction DR1.

In an embodiment, the head management part MP may include the cleaning unit, and the sub-head management part SMP may include the inspection unit. In this case, as illustrated in FIG. 14, the head management apparatus MAA′ may clean the head part HP after the head management part MP moves in the second direction DR2 so as to overlap the head part HP in a plan view. In order to correspond to the nozzles NZ repeatedly arranged along the second direction DR2, the head management apparatus MAA′ may move in the second direction DR2 or in the opposite direction to the second direction DR2. The first to third head management units MAA1, MAA2, MAA3 may clean the head part HP. To correspond to the nozzles NZ repeatedly arranged along the first direction DR1, each of the first to third head management units MAA1, MAA2, MAA3 may move in the first direction DR1 or in the opposite direction to the first direction DR1.

In addition, the sub-head management part SMP may inspect the head part HP after the sub-head management part SMP moves in the opposite direction to the first direction DR1 so as to overlap the head part HP in a plan view. To correspond to the nozzles NZ repeatedly arranged along the first direction DR1, the sub-head management part SMP may move in the first direction DR1 or in the opposite direction to the first direction DR1. The first and second sub-head management units SMA1, SMA2 may inspect the head part HP. To correspond to the nozzles NZ repeatedly arranged along the second direction DR2, each of the first and second sub-head management units SMA1, SMA2 may move in the second direction DR2 or in the opposite direction to the second direction DR2.

In another embodiment, the head management part MP may include the inspection unit, and the sub-head management part SMP may include the cleaning unit. In this case, the head management apparatus MAA′ may inspect the head part HP after the head management part MP moves in the second direction DR2 to overlap the head part HP in a plan view. In addition, the sub-head management part SMP may clean the head part HP after the sub-head management part SMP moves in the opposite direction to the first direction DR1 so as to overlap the head part HP in a plan view.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. An inkjet printing apparatus, the apparatus comprising:
a base;
a stage disposed on the base and capable of moving a substrate in a first direction;
a first column part disposed on the base;
a second column part disposed on the base and spaced apart from the first column part in the first direction;
a head part configured to eject ink on the substrate at a fixed position and disposed on the stage; and
a head management part disposed between the first column part and the second column part and capable of moving in a second direction intersecting the first direction.

2. The apparatus of claim 1, wherein the head management part is spaced apart from the head part in a plan view.

3. The apparatus of claim 1,
wherein the head part defines a workspace to which the ink is ejected,
wherein the workspace overlaps the head part in a plan view, and
wherein after the head part ejects the ink on the substrate, the stage moves in the first direction so as to move away from the workspace.

4. The apparatus of claim 3, wherein after the stage moves in the first direction away from the workspace, the head management part moves in the second direction toward the workspace.

5. The apparatus of claim 4, wherein the head management part includes:
a head management apparatus configured to manage the head part; and
a head management frame on which the head management apparatus is loaded.

6. The apparatus of claim 5, wherein the head management frame is adjacent to each of the first column part and the second column part in the first direction and has a U-shape in a side view.

7. The apparatus of claim 5, wherein the head management apparatus includes:
a cleaning unit configured to clean the head part; and
an inspection unit configured to inspect the head part.

8. The apparatus of claim 5, further comprising:
a sub-head management part spaced apart from the stage in the first direction and capable of moving in the first direction.

9. The apparatus of claim 8, wherein after the stage moves in the first direction away from the workspace, the sub-head management part moves in the first direction toward the workspace.

10. The apparatus of claim 8,
wherein the head management apparatus includes a cleaning unit configured to clean the head part, and
wherein the sub-head management part includes an inspection unit configured to inspect the head part.

11. The apparatus of claim 8,
wherein the head management apparatus includes an inspection unit configured to inspect the head part, and
wherein the sub-head management part includes a cleaning unit configured to clean the head part.

12. The apparatus of claim 1, further comprising:
an ink supply part configured to supply the ink to the head part and disposed on the head part.

13. The apparatus of claim 12,
wherein the head part is supported by a first structure,
wherein the ink supply part is supported by a second structure different from the first structure, and
wherein the first structure and the second structure are spaced apart from each other.

14. The apparatus of claim 1,
wherein each of the first column part and the second column part is provided in plural,
wherein the plurality of first column parts are spaced apart from each other in the second direction, and
wherein the plurality of second column parts are spaced apart from each other in the second direction.

15. The apparatus of claim 14, further comprising:
a first bridge disposed on the plurality of first column parts, extending in the second direction, and connecting the plurality of first column parts; and
a second bridge disposed on the plurality of second column parts, extending in the second direction, and connecting the plurality of second column parts.

16. The apparatus of claim 15, wherein the head part is fixed by the first bridge and the second bridge.

17. An inkjet printing method, the method comprising:
providing a stage disposed on a base and on which a substrate is loaded, a first column part and a second column part spaced apart from each other in a first direction and disposed on the base, a head part disposed on the stage, and a head management part disposed between the first column part and the second column part;
transporting the substrate in the first direction by the stage;
ejecting ink on the substrate by the head part while a position of the head part is fixed; and
transporting the head management part in a second direction intersecting the first direction to overlap the head part in a plan view.

18. The method of claim 17, wherein when the head management part is disposed between the first column part and the second column part, the head management part is spaced apart from the head part in the plan view.

19. The method of claim 17,
wherein the head part defines a workspace to which the ink is ejected,
wherein the workspace overlaps the head part in the plan view, and
wherein after the ejecting of the ink on the substrate, the stage moves in the first direction so as to move away from the workspace.

20. The method of claim 19, wherein after the stage moves in the first direction away from the workspace, the head management part moves in the second direction toward the workspace.

21. The method of claim 17, further comprising:
cleaning the head part and inspecting the head part after the transporting of the head management part in the second direction.

22. The method of claim 17, further comprising:
providing a sub-head management part spaced apart from the stage in the first direction before the transporting of the substrate in the first direction.

23. The method of claim 22, further comprising:
transporting the sub-head management part in the first direction so as to overlap the head part in the plan view after the ejecting of the ink on the substrate.

24. The method of claim 23, further comprising:
cleaning the head part by the head management part after the transporting of the head management part in the second direction; and
inspecting the head part by the sub-head management part after the transporting of the sub-head management part in the first direction.

25. The method of claim 23, further comprising:
inspecting the head part by the head management part after the transporting of the head management part in the second direction; and
cleaning the head part by the sub-head management part after the transporting of the sub-head management part in the first direction.
